(19) United States
(12) Patent Application Publication
(10) Pub. No.: US 2021/0408070 A1
(43) Pub. Date: Dec. 30, 2021

(54) ARRAY SUBSTRATE AND METHOD FOR FABRICATING SAME

(71) Applicant: WUHAN CHINA STAR OPTOELECTRONICS TECHNOLOGY CO., LTD., Wuhan (CN)

(72) Inventor: Hanchen LIU, Wuhan (CN)

(73) Assignee: WUHAN CHINA STAR OPTOELECTRONICS TECHNOLOGY CO., LTD., Wuhan (CN)

(21) Appl. No.: 16/630,480

(22) PCT Filed: Nov. 8, 2019
(86) PCT No.: PCT/CN2019/116444

§ 371 Date: Jan. 13, 2020

(30) Foreign Application Priority Data
Feb. 22, 2019 (CN) 201910777809.8

(51) Int. Cl. H01L 27/12

(52) U.S. Cl. CPC H01L 27/1225; H01L 27/127

(57) ABSTRACT

An array substrate and a method for fabricating same are provided. Base on the existing process, the order of forming the coating film of the thin film transistor and forming the photoresist are adjusted. Thus, a patterning treatment can be directly performed on the first coating film, such that an etching process on the first coating film in the later can be avoided. Therefore, the etching process in the patterning treatment can be omitted, the fabrication process can be simplified, the production efficiency of the product can be improved, and the cost can be reduced.

### FIELD OF INVENTION

The present disclosure relates to the field of display technologies, and more particularly, to an array substrate and a method for fabricating same.

### BACKGROUND OF INVENTION

In the field of thin film transistor liquid crystal displays and active matrix organic light emitting diode (AMOLED) displays, oxide semiconductor material represented by indium gallium zincoxide (IGZO) have become hot spots. At present, the structure of IGZO thin film transistor array substrate mainly has three types: etching barrier type, back channel etching type, and coplanar type. The manufacturing process of the etch barrier type is relatively simple. The etching barrier layer on IGZO can protect the IGZO layer from being damaged when the source/drain electrode (S/D) is formed, such that the performance of IGZO can be enhanced. The material of the etching barrier layer is generally SiNx or SiOx. However, the formation of the etching barrier layer requires an additional photolithography process, which increases the number of the manufacturing processes.

### Technical Problems

The manufacturing process of the above IGZO thin film transistor array substrate are as follow: forming the aforementioned layers on the substrate by six patterning processes, wherein the patterning process includes a part or all of the processes, such as photoresist coating, masking, exposure, development, etching, and photoresist stripping. A gate electrode mask, an active layer mask, an etching barrier mask, a source and drain electrode mask, a passivation layer mask, and a pixel electrode mask are used in the patterning processes. The manufacturing processes of the above thin film transistor array substrate include multiple patterning processes. The multiple and complicated processes result in a long production cycle, a high difficulty for scheduling, and a high manufacturing costs.

### SUMMARY OF INVENTION

### Technical Solutions

The embodiments of the present disclosure provide an array substrate and a method for fabricating thereof. Compared with the traditional fabricating process, a first coating film is formed first, and then a first photoresist is formed on the coating film. The present disclosure uses the above fabricating method, forming a first photoresist layer, and performing a patterning treatment on the first photoresist layer. Then, forming a first coating film on the patterned first photoresist layer. That is, based on the existing process, the order of forming the coating film of the thin film transistor and of forming the photoresist are adjusted. Thus, a patterning treatment can be directly performed on the first coating film, such that an etching process on the first coating film in the later can be avoided. Therefore, the etching process in the patterning treatment can be omitted, the fabrication process can be simplified, the production efficiency of the product can be improved, and the cost can be reduced.

In order to solve the aforementioned problems, in a first aspect, the present application provides a method for fabricating an array substrate, including steps of:

providing a substrate;

adjusting a solubility of a photoresist material;

coating the photoresist material on the substrate to form a first photoresist layer, so as to control a lateral side depression angle of a second photoresist layer, wherein the first photoresist layer is a negative photoresist;

forming a first coating film on the second photoresist layer;

performing a post-baking treatment on the second photoresist layer to remove the first coating film on a lateral side of the second photoresist layer;

adding a stripper to the lateral side of the second photoresist layer to remove the second photoresist layer to form a second coating film.

Further, the step of performing the post-baking treatment on the second photoresist layer to remove the first coating film on the lateral side of the second photoresist layer further includes:

using a hot-melt polymer material to form the second photoresist layer.

Further, the step of performing the stripping treatment on the second photoresist layer to form the second coating film includes:

performing a plasma treatment on the first coating film to generate cracks on a surface of the first coating film; and

adding the stripper on the surface of the first coating film so that the stripper spreads through the cracks, to remove the second photoresist layer to form the second coating film.

Further, the step of forming the first photoresist layer on the substrate includes:

coating a first photoresist on the substrate to form the first photoresist layer.

Further, the step of performing the patterning treatment on the first photoresist layer to form the second photoresist layer includes:

performing an exposure and development treatment on the first photoresist layer to form the second photoresist layer.

Further, the second photoresist layer is made of an elastic material.

Further, the second photoresist layer is made of a hot-melt material.

Further, the second coating film is one of a light-shielding layer, a gate layer, a gate insulating layer, an active layer, a source/drain electrode layer, a passivation layer, and a pixel electrode layer.

In a second aspect, the present application further provides a method for fabricating an array substrate, including steps of:

providing a substrate;

forming a first photoresist layer on the substrate;

performing a patterning treatment on the first photoresist layer to form a second photoresist layer;

forming a first coating film on the second photoresist layer; and

performing a stripping treatment on the second photoresist layer to form a second coating film.

Further, the step of performing the stripping treatment on the second photoresist layer to form the second coating film includes:

performing a post-baking treatment on the second photoresist layer to remove the first coating film on a lateral side of the second photoresist layer; and

adding a stripper to the lateral side of the second photoresist layer to remove the second photoresist layer to form the second coating film.

Further, the first photoresist layer is a negative photoresist, and the step of forming the first photoresist layer on the substrate includes:

adjusting a solubility of a photoresist material; and

coating the photoresist material on the substrate to form a first photoresist layer, so as to control a lateral side depression angle of a second photoresist layer.

Further, the step of performing the post-baking treatment on the second photoresist layer to remove the first coating film on the lateral side of the second photoresist layer further includes:

using a hot-melt polymer material to form the second photoresist layer.

Further, the step of performing the stripping treatment on the second photoresist layer to form the second coating film includes:

performing a plasma treatment on the first coating film to generate cracks on a surface of the first coating film; and

adding the stripper on the surface of the first coating film so that the stripper spreads through the creaks, to remove the second photoresist layer to form the second coating film.

Further, the step of forming the first photoresist layer on the substrate includes:

coating a first photoresist on the substrate to form the first photoresist layer.

Further, the step of performing the patterning treatment on the first photoresist layer to form the second photoresist layer includes:

performing an exposure and development treatment on the first photoresist layer to form the second photoresist layer.

Further, the second photoresist layer is made of an elastic material or a hot-melt material.

Further, the second coating film is one of a light-shielding layer, a gate layer, a gate insulating layer, an active layer, a source/drain electrode layer, a passivation layer, and a pixel electrode layer.

In a third aspect, the present application further provides an array substrate, wherein the array substrate is formed by the above method for fabricating an array substrate.

Beneficial Effect:

The embodiment of the present disclosure provides a method for fabricating an array substrate, the method includes steps of: providing a substrate; forming a first photoresist layer on the substrate; performing a patterning treatment on the first photoresist layer to form a second photoresist layer; forming a first coating film on the second photoresist layer; and performing a stripping treatment on the second photoresist layer to form a second coating film. Compared with the traditional fabricating process, a first coating film is formed first, and then a first photoresist is formed on the coating film. The present disclosure uses the above fabricating method, forming a first photoresist layer, performing a patterning treatment on the first photoresist layer, and then, forming a first coating film on the patterned first photoresist layer. That is, based on the existing process, the order of forming the coating film of the thin film transistor and forming the photoresist are adjusted. Thus, a patterning treatment can be directly performed on the first coating film, such that an etching process on the first coating film later can be avoided. Therefore, the etching process in the patterning treatment can be omitted, the fabrication process can be simplified, the production efficiency of the product can be improved, and the cost can be reduced.

### DESCRIPTION OF DRAWINGS

In order to more clearly illustrate the technical solutions in the embodiments or the prior art, the following drawings, which are intended to be used in the description of the embodiments or the prior art, will be briefly described. It is obvious that the drawings and the following description are only some embodiments of the present disclosure. Those of ordinary skill in the art may, without creative efforts, derive other drawings from these drawings.

FIG. 1 is a schematic flowchart of a method for fabricating an array substrate according to one embodiment of the present disclosure.

FIG. 2 is a schematic flowchart of a method for fabricating an array substrate according to another embodiment of the present disclosure.

FIG. 3 is a schematic structural diagram of an array substrate according to one embodiment of the present disclosure.

FIG. 4 is a schematic structural diagram of an array substrate according to another embodiment of the present disclosure.

FIG. 5 is a schematic flowchart of a method for fabricating an array substrate according to another embodiment of the present disclosure.

### DETAILED DESCRIPTION OF PREFERRED EMBODIMENTS

In the following, the technical solutions in the embodiments of the present disclosure will be clearly and completely described with reference to the drawings in the embodiments of the present disclosure. Obviously, the described embodiments are only a part of the embodiments of the present disclosure, but not all of the embodiments. Based on the embodiments of the present disclosure, all other embodiments obtained by those skilled in the art without creative work fall into the protection scope of the present disclosure.

In the following detailed description of the preferred embodiments, reference is made to the accompanying drawings which form a part hereof, and in which is shown by way of illustrating specific embodiments in which the disclosure may be practiced. In this regard, directional terminology, such as “top”, “bottom”, “front”, “back”, “left”, “right”, “inside”, “outside”, “side”, etc., is used with reference to the orientation of the figure(s) being described. As such, the directional terminology is used for purposes of illustration and is in no way limiting. Throughout this specification and in the drawings, like parts will be referred to by the same reference numerals. In addition, the terms “first” and “second” are used for descriptive purposes only and cannot be understood as indicating or implying relative importance or implicitly indicating the number of technical features indicated. Therefore, the features defined as “first” and “second” may explicitly or implicitly include one or more of the features. In the description of the present disclosure, the meaning of “plurality” is two or more, unless specifically defined otherwise.

In this application, the word “exemplary” is used to mean “serving as an example, illustration, or illustration.” Any embodiment described as “exemplary” in this application is not necessarily to be construed as preferred or advantageous over other embodiments. In order to enable any person skilled in the art to implement and use the present disclosure, the following description is given. In the following description, details are set forth for the purpose of explanation. It should be understood by one of ordinary skill in the art that the present disclosure may be implemented without the use of these specific details. In other instances, well-known structures and procedures are not described in detail to avoid obscuring the description of the present disclosure with unnecessary details. Accordingly, the disclosure is not intended to be limited to the embodiments shown, but is to be accorded the widest scope consistent with the principles and features disclosed herein.

The manufacturing process of the existing IGZO thin film transistor array substrate are as follow: forming the aforementioned layers on the substrate by six patterning processes, wherein the patterning process includes a part or all of the processes, such as photoresist coating, masking, exposure, development, etching, and photoresist stripping. A gate electrode mask, an active layer mask, an etching barrier mask, a source and drain electrode mask, a passivation layer mask, and a pixel electrode mask are used in the patterning processes. The manufacturing processes of the above thin film transistor array substrate include multiple patterning processes. The multiple and complicated processes result in a long production cycle, a high difficulty for scheduling, and a high manufacturing costs.

Based on this, the embodiment of the present disclosure provides an array substrate and a method for fabricating thereof, which are described in detail below respectively.

First, the embodiment of the present disclosure provides a method for fabricating an array substrate. The method includes steps of: providing a substrate; forming a first photoresist layer on the substrate; performing a patterning treatment on the first photoresist layer to form a second photoresist layer; forming a first coating film on the second photoresist layer; and

performing a stripping treatment on the second photoresist layer to form a second coating film.

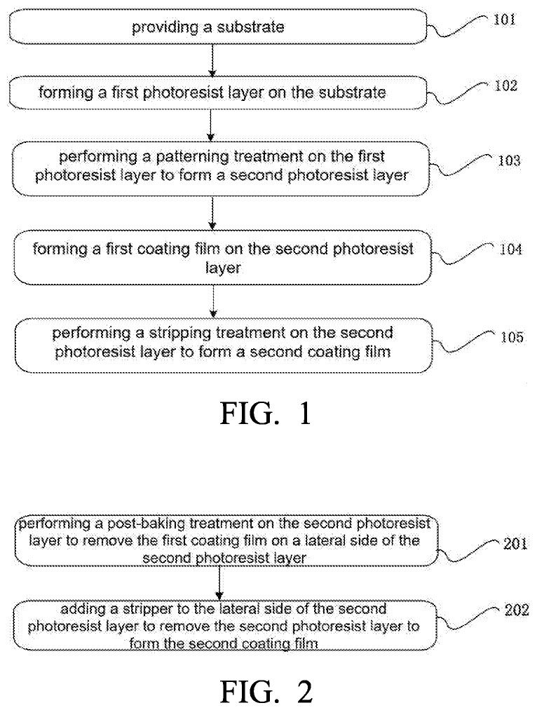

As shown in FIG. 1, FIG. 1 is a schematic flowchart of a method for fabricating an array substrate according to one embodiment of the present disclosure, wherein the method includes steps of:

Step 101, providing a substrate.

Specifically, the substrate may be made of inorganic materials, such as glass, or may include other prepared coatings.

Step 102, forming a first photoresist layer on the substrate.

Photoresists (or photo resin, PR) are an organic compound. According to the relationship between the cross-linking reaction in the photoresist and ultraviolet rays, the photoresists are divided into positive photoresists and negative photoresists. Array engineering generally use positive photoresists, and color film engineering generally use negative photoresists. For a positive photoresist, the photoresist in the area irradiated by ultraviolet rays undergoes a cross-linking decomposition reaction, and this part can be dissolved in the developing solution. For a negative photoresist, the photoresist in the area irradiated with ultraviolet rays undergoes a cross-linking reaction, and this part is difficult to be dissolved in the developing solution. The characteristics of the photoresist for the array engineering must meet the requirements of the coating process, exposure process, etching process, development process and stripping process. In order to meet the requirements of those process, the photoresist is required to have desirable coating property, uniform film thickness, and adhesion to the substrate material. In addition, for the photoresist, it is also required that the development residual film rate of the photoresist is low, the etching resistance selection ratio is high, and stripping is easy.

Photoresist material is a hydrophobic chemical. For a film surface with desirable hydrophilicity, the adhesion of the coated photoresist layer to its contact interface is poor, resulting in peeling of the coated photoresist layer or generating holes on the coated photoresist layer. Before coating a photoresist, the surface of the film is treated with hexamethyldisilazide (HMDS, which has amphiphilic characteristics), which can enhance the wettability of the surface of the photoresist and the film, so as to achieve a desirable coating effect. The surface of the metal film layer (except Mo) is generally hydrophobic and can be in effective contact with the photoresist. Non-metallic film surfaces, such as a-Si:H and SiNx, are highly hydrophilic on their surfaces, so HMDS treatment is required therefor before photoresist coating. The surface of the film shows a hydrophilic —OH group. After HMDS treatment, an NH— bond in HMDS is broken and is bond to an OH group. The reaction generates hydrophobic (CH3)3SiO— and NH3 gas, which improves the photoresist coating property.

Step 103, performing a patterning treatment on the first photoresist layer to form a second photoresist layer.

Specifically, the first photoresist layer is subjected to an exposure process, and a pattern on the mask is transferred to the first photoresist layer to form a second photoresist layer having the pattern.

Step 104, forming a first coating film on the second photoresist layer.

Specifically, in fabricating each layer of the thin film of the pixel array, the thin films can be divided into two categories: conductive films and functional films. The conductive films include a metal film and a transparent indium tin oxide (ITO) film, and the functional films include metal films with a light-shielding effect, hydrogen silicon nitride films (SiN:H) with an insulating effect, hydrogenated amorphous silicon (a-Si:H) with a semiconductor function, phosphorus-doped hydrogenated amorphous silicon acting as an ohmic contact. In the embodiment of the present disclosure, the first coating film may be the conductive films and the functional films described above. The types of the first coating films are not limited in this application, and depend on the actual situation.

Step 105, performing a stripping treatment on the second photoresist layer to form a second coating film.

Stripping the second photoresist with a stripper leaves a patterned second coating film, and the corresponding layer structure of the pixel array is completed. For example, the stripper used in this step is a chemical agent capable of dissolving the photoresist. Specifically, the strippers include alkaline strippers and organic strippers, wherein the alkaline strippers are composed of potassium hydroxide, glycol ether, amine, and deionized water. The weight ratio of each component in the strippers may be potassium hydroxide ranging from 15.8 to 17.8%, glycol ether ranging from 14.0 to 16.0%, amine ranging from 51.0 to 55.0%, and the rest being deionized water. The organic stripper is composed of polyvinyl glycol ether, polyoxyethylene alkyl ether, chelating dispersant, preservative, electrolyte and deionized water. The weight ratio of each component in the stripper may be polyethylene glycol ether ranging from 5 to 20%, polyoxyethylene alkyl ether ranging from 5 to 20%, chelating dispersant ranging from 5 to 10%, preservative ranging from 1 to 5%, and electrolyte ranging from 3 to 15%, and the rest being deionized water. Of course, the proportion of the constituents of the stripper can be determined according to the actual conditions, such as the thickness of the photoresist and the thickness of the film deposited thereon.

It should be noted that, the embodiment of a method for fabricating an array substrate only describes the above steps. It can be understood that, in addition to the above preparation steps, the method for fabricating an array substrate provided by the present disclosure further includes any other necessary fabricating process, such as coating, exposure, development, and stripping.

The embodiment of the present disclosure provides a method for fabricating an array substrate, the method includes steps of: providing a substrate; forming a first photoresist layer on the substrate; performing a patterning treatment on the first photoresist layer to form a second photoresist layer; forming a first coating film on the second photoresist layer; and performing a stripping treatment on the second photoresist layer to form a second coating film. Compared with the traditional fabricating process, a first coating film is formed first, and then a first photoresist is formed on the coating film. The present disclosure uses the above fabricating method, forming a first photoresist layer, and performing a patterning treatment on the first photoresist layer, and then, forming a first coating film on the patterned first photoresist layer. That is, based on the existing process, the order of forming the coating film of the thin film transistor and forming the photoresist are adjusted. Thus, a patterning treatment can be directly performed on the first coating film, such that an etching process on the first coating film later can be avoided. Therefore, the etching process in the patterning treatment can be omitted, the fabrication process can be simplified, the production efficiency of the product can be improved, and the cost can be reduced.

Based on the above embodiment, in another specific embodiment of the present application, the step of performing the stripping treatment on the second photoresist layer to form the second coating film includes: performing a post-baking treatment on the second photoresist layer to remove the first coating film on a lateral side of the second photoresist layer; and adding a stripper to the lateral side of the second photoresist layer to remove the second photoresist layer to form the second coating film.

As shown in FIG. 2, FIG. 2 is a schematic flowchart of a method for fabricating an array substrate according to another embodiment of the present disclosure, wherein the step of performing the stripping treatment on the second photoresist layer to form the second coating film may include:

Step 201, performing a post-baking treatment on the second photoresist layer to remove the first coating film on a lateral side of the second photoresist layer.

Specifically, after a low-temperature film formation is performed on the second photoresist layer at 100-120° C., and then a post-baking treatment is performed at 220-240° C., the lateral side of the second photoresist layer is deformed to damage the first coating film on the lateral side of the second photoresist layer. For example, the temperature of the low-temperature film formation may be set at 110° C., and the temperature of the post-baking treatment may be set at 230° C.

Step 202, adding a stripper to the lateral side of the second photoresist layer to remove the second photoresist layer to form the second coating film.

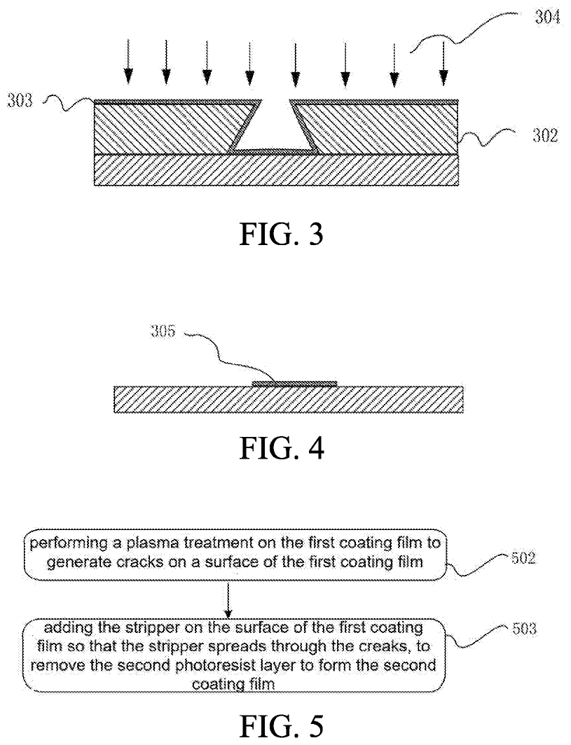

Specifically, as shown in FIG. 3 and FIG. 4, when the first coating film on the lateral side of the second photoresist layer is damaged, the stripper 304 may contact the second photoresist layer from the lateral side. After the second photoresist layer is stripped, the second coating film 305 having the same pattern as the second photoresist layer is formed. Therefore, the corresponding film structure of the pixel array is completed.

Based on the above embodiment, in another specific embodiment of the present application, the first photoresist layer is a negative photoresist, and the step of forming the first photoresist layer on the substrate includes steps of:

adjusting a solubility of a photoresist material, and coating the photoresist material on the substrate to form a first photoresist layer, so as to control a lateral side depression angle of a second photoresist layer.

Specifically, when the first photoresist is a negative photoresist, the lateral side depression angle of the second photoresist layer can be controlled by adjusting the solubility of the photoresist material, which can help the first coating film on the lateral side of the second photoresist layer to collapse and deform after the post-baking treatment.

Based on the above embodiment, in another specific embodiment of the present application, the step of performing the post-baking treatment on the second photoresist layer to remove the first coating film on the lateral side of the second photoresist layer further includes:

using a hot-melt polymer material to form the second photoresist layer.

Specifically, forming the second photoresist layer by using a hot-melt polymer material may increase the melt flow effect of the post-baking process, so as to damage the structure of the first coating film on the lateral side of the second photoresist layer. Therefore, the stripper in subsequent operations spreads through the lateral side of the second photoresist layer more easily to remove the second photoresist layer, wherein the polymer material with a flexible structure may be polymethyl methacrylate (PMMA).

Based on the above embodiment, in another specific embodiment of the present application, the step of performing the stripping treatment on the second photoresist layer to form the second coating film includes: performing a plasma treatment on the first coating film to generate cracks on a surface of the first coating film; and adding the stripper on the surface of the first coating film so that the stripper spreads through the creaks, to remove the second photoresist layer to form the second coating film.

As shown in FIG. 5, FIG. 5 is a schematic flowchart of a method for fabricating an array substrate according to another embodiment of the present disclosure, wherein the step of performing physical methods, such as a stripping treatment, a brush treatment, or a high-pressure water vapor two fluid impact on the second photoresist layer to form the second coating film includes steps of:

Step 501, using a polymer material with a flexible structure to as the second photoresist layer, wherein the polymer material with a flexible structure may be polymethyl methacrylate (PMMA).

Step 502, performing physical methods, such as a stripping treatment, a brush treatment, or a high-pressure water vapor two fluid impact on the first coating film to generate cracks on a surface of the first coating film.

Step 503, adding the stripper on the surface of the first coating film so that the stripper spreads through the creaks, to remove the second photoresist layer to form the second coating film.

Based on the above embodiment, in another specific embodiment of the present application, the step of forming the first photoresist layer on the substrate includes:

coating a first photoresist on the substrate to form the first photoresist layer.

Specifically, coating the photoresist coating includes three steps: a PR coating, a low-pressure drying, and a pre-baking (also known as pre-baking).

There are three main coating methods for photoresist: spin coating, blade coating combined with spin coating, and fine blade coating. The first two methods are generally used in the lower generation production line. The fine blade coating is used in high generation production line to be adapted to the requirements of large sizes of glass substrates and large-scale productions. For the photoresist in the fine blade coating, a strip-shaped nozzle is used to precisely control the distance between the nozzle and the substrate, the amount of photoresist, and the nozzle moving speed, so as to achieve rapid and uniform coating on the substrate surface. During the photoresist coating process, a part of the photoresist is left on the edge of the nozzle. After this part of the photoresist is cured, it may affect the liquid photoresist coating effect and produce a coating Mura. Therefore, it is necessary to periodically clean the nozzle with a solvent (PGME/PGMEA=7:3) that can quickly dissolve the photoresist to ensure the cleanliness of the nozzle.

The low-pressure drying uses the low-pressure environment to reduce the boiling point of the solvent in the photoresist, which can make the solvent quickly escape from the surface to achieve the purpose of removing most solvents. In order to make the solvent escape uniformly, it is necessary to control the decreasing rate of the vacuum pressure to avoid the Mura formed by non-uniform escape. After low-pressure drying, the substrate is transferred to a hot machine for the pre-baking. The temperature of the pre-baking generally ranges from 100 to 150° C., so that the solvent in the photoresist is volatilized, and at the same time, the photoresist is solidified and hardened, and the adhesion between the photoresist and the substrate is enhanced. The temperature and time of the pre-baking have an influence on the line width and uniformity of the photoresist after exposure.

Based on the above embodiment, in another specific embodiment of the present application, the step of performing the patterning treatment on the first photoresist layer to form the second photoresist layer includes:

performing an exposure and development treatment on the first photoresist layer to form the second photoresist layer.

The photoresist development process is a process in which the photoresist irradiated with ultraviolet rays is dissolved in a developing solution after the substrate is exposed. The components of the photoresist include a resin, a photosensitizer, and a functional solvent. During the exposure process, the photoresist undergoes a cross-linking decomposition reaction in the area irradiated by ultraviolet rays, and the resin is dissolved in the developing solution. In areas not irradiated by ultraviolet rays, the cross-linking of the photoresist maintains the original characteristics and prevents the resin from being dissolved in the developing solution.

Early developers were strongly alkaline sodium or potassium hydroxide aqueous solutions. Both of these developing solutions contain a large amount of mobile sodium and potassium ions, residues of which on the film surface seriously affect the electrical characteristics of the device. In the current development process, an aqueous solution of tetramethylammonium hydroxide (TMAH) is commonly used for development. TMAH developer solution has a very low metal ion concentration, which can avoid the influence of mobile ions on the electrical characteristics of the device. However, if the development time is too long, the photoresist that is not irradiated by ultraviolet rays may gradually be dissolved in the developing solution.

Based on the above embodiment, in another specific embodiment of the present application, the second photoresist layer is made of an elastic material or a hot-melt material. For example, the elastic material may be a polyimide (PI).

Based on the above embodiment, in another specific embodiment of the present application, the second coating film is one of a light-shielding layer, a gate layer, a gate insulating layer, an active layer, a source/drain electrode layer, a passivation layer, and a pixel electrode layer.

Specifically, during the fabricating process of the thin film transistor array substrate, the gate layer, gate insulating layer, the active layer, the source/drain electrode layer, the passivation layer, and the pixel electrode layer included in the thin film transistor array substrate can be fabricated in the above manner.

In order to better implement the method for fabricating the array substrate in the embodiment of the present disclosure, on the basis of the method for fabricating the array substrate, the embodiment of the present disclosure further provides an array substrate, wherein the array substrate is formed by the method for fabricating an array substrate in the above embodiments.

It should be noted that only the above structure is described in the above embodiment of the array substrate. It can be understood that, in addition to the above structure, the display panel according to the embodiment of the present disclosure may further include any other necessary structures, such as a substrate, a buffer layer, and an interlayer dielectric layer, etc., which are not specifically limited herein.

By using the array substrate described in the above embodiments, the performance of the display device is further improved.

In the above embodiments, the description of each embodiment has its own emphasis. For a part that is not described in detail in an embodiment, reference may be made to the foregoing detailed description of other embodiments, and details are not described herein.

In specific implementation, each of the above units or structures can be implemented as independent entities, or any combination can be implemented as the same or several entities. For specific implementation of the foregoing units or structures, reference may be made to the foregoing method embodiments, and details are not described herein again.

For specific implementation of the foregoing operations, refer to the foregoing embodiments, and details are not described herein again.

The array substrate and the method for fabricating thereof provided in the embodiments of the present disclosure have been described in detail above. Specific examples are used herein to explain the principle and implementation of the present disclosure. The description of the above embodiments is only used to help understand the method and core idea of the present disclosure. At the same time, for those skilled in the art, according to the idea of the present disclosure, there will be changes in the specific implementation and application scope. In summary, the content of this specification should not be construed as a limitation on the present disclosure.

1. A method for fabricating an array substrate, comprising steps of:
providing a substrate;
adjusting a solubility of a photoresist material;
coating the photoresist material on the substrate to form a first photoresist layer, so as to control a side depression angle of a second photoresist layer, wherein the first photoresist layer is a negative photoresist;
performing a patterning treatment on the first photoresist layer to form the second photoresist layer;
forming a first coating film on the second photoresist layer;
performing a post-baking treatment on the second photoresist layer to remove the first coating film on a side of the second photoresist layer; and
adding a stripper to the side of the second photoresist layer to remove the second photoresist layer to form a second coating film.

2. The method for fabricating an array substrate according to claim 1, wherein the step of performing the post-baking treatment on the second photoresist layer to remove the first coating film on the side of the second photoresist layer further comprises:
using a hot-melt polymer material to form the second photoresist layer.

3. The method for fabricating an array substrate according to claim 1, wherein the step of performing the stripping treatment on the second photoresist layer to form the second coating film comprises:
performing a plasma treatment on the first coating film to generate cracks on a surface of the first coating film; and
adding the stripper on the surface of the first coating film so that the stripper spreads through the cracks, to remove the second photoresist layer to form the second coating film.

4. The method for fabricating an array substrate according to claim 1, wherein the step of forming the first photoresist layer on the substrate comprises:
coating a first photoresist on the substrate to form the first photoresist layer.

5. The method for fabricating an array substrate according to claim 1, wherein the step of performing the patterning treatment on the first photoresist layer to form the second photoresist layer comprises:
performing an exposure and development treatment on the first photoresist layer to form the second photoresist layer.

6. The method for fabricating an array substrate according to claim 1, wherein the second photoresist layer is made of an elastic material.

7. The method for fabricating an array substrate according to claim 1, wherein the second photoresist layer is made of a hot-melt material.

8. The method for fabricating an array substrate according to claim 1, wherein the second coating film is one of a light-shielding layer, a gate layer, a gate insulating layer, an active layer, a source/drain electrode layer, a passivation layer, and a pixel electrode layer.

9. A method for fabricating an array substrate, comprising steps of:
providing a substrate;
forming a first photoresist layer on the substrate;
performing a patterning treatment on the first photoresist layer to form a second photoresist layer;
forming a first coating film on the second photoresist layer; and
performing a stripping treatment on the second photoresist layer to form a second coating film.

10. The method for fabricating an array substrate according to claim 9, wherein the step of performing the stripping treatment on the second photoresist layer to form the second coating film comprises:
performing a post-baking treatment on the second photoresist layer to remove the first coating film on a side of the second photoresist layer; and
adding a stripper to the side of the second photoresist layer to remove the second photoresist layer to form the second coating film.

11. The method for fabricating an array substrate according to claim 9, wherein the first photoresist layer is a negative photoresist, and the step of forming the first photoresist layer on the substrate comprises:
adjusting a solubility of a photoresist material; and
coating the photoresist material on the substrate to form a first photoresist layer, so as to control a side depression angle of a second photoresist layer.

12. The method for fabricating an array substrate according to claim 10, wherein the step of performing the post-baking treatment on the second photoresist layer to remove the first coating film on the side of the second photoresist layer further comprises:
using a hot-melt polymer material to form the second photoresist layer.

13. The method for fabricating an array substrate according to claim 9, wherein the step of performing the stripping treatment on the second photoresist layer to form the second coating film comprises:
performing a plasma treatment on the first coating film to generate cracks on a surface of the first coating film; and
adding the stripper on the surface of the first coating film so that the stripper spreads through the creaks, to remove the second photoresist layer to form the second coating film.

14. The method for fabricating an array substrate according to claim 9, wherein the step of forming the first photoresist layer on the substrate comprises:
coating a first photoresist on the substrate to form the first photoresist layer.

15. The method for fabricating an array substrate according to claim 9, wherein the step of performing the patterning treatment on the first photoresist layer to form the second photoresist layer comprises:
performing an exposure and development treatment on the first photoresist layer to form the second photoresist layer.

16. The method for fabricating an array substrate according to claim 9, wherein the second photoresist layer is made of an elastic material.

17. The method for fabricating an array substrate according to claim 9, wherein the second photoresist layer is made of a hot-melt material.

18. The method for fabricating an array substrate according to claim 9, wherein the second coating film is one of a light-shielding layer, a gate layer, a gate insulating layer, an active layer, a source/drain electrode layer, a passivation layer, and a pixel electrode layer.

19. An array substrate, wherein the array substrate is formed by the method for fabricating an array substrate according to claim 9.
